(19) United States
(12) Patent Application Publication
(10) Pub. No.: US 2016/0155583 A1
(43) Pub. Date: Jun. 2, 2016

(54) CIRCUIT BOARD AND ELECTRONIC KEY USING SAME

(71) Applicant: KABUSHIKI KAISHA TOKAI RIKA DENKI SEISAKUSHO, Aichi (JP)

(72) Inventors: Daisuke SENZAKI, Aichi (JP); Yuki KONO, Aichi (JP); Masayuki KAWAMURA, Aichi (JP); Hiroaki KOJIMA, Aichi (JP)

(21) Appl. No.: 14/955,846

(22) Filed: Dec. 1, 2015

(30) Foreign Application Priority Data
Dec. 2, 2014 (JP) 2014-243927

(51) Int. Cl. H01H 13/7065; H05K 1/02; H01R 12/70

(52) U.S. Cl. CPC H01H 13/7065; H01R 12/7076; H05K 1/0296; H01H 2231/032

(57) ABSTRACT

A circuit board includes a circuit board pattern forming a part of an electronic circuit and including a mounting pattern group on which a receiving means for receiving an operation can be mounted. The electronic circuit is established even when the receiving means is mounted on any mounting pattern of the mounting pattern group.

The present application is based on Japanese patent application No. 2014-243927 filed on Dec. 2, 2014, the entire contents of which are incorporated herein by reference.

### BACKGROUND OF THE INVENTION

1. Field of the Invention

The invention relates to a circuit board and an electronic key using the circuit board.

2. Related Art

A mobile device for an electronic key system is provided with a case which forms the outline of a main body of the mobile device and encloses a circuit board mounting a communication circuit for wirelessly communicating with an external device, a protective cover placed over one side of the circuit board, and a plate-shaped battery holder placed over the other side of the circuit board to hold a battery (see e.g., JP-A-2008-196194).

### SUMMARY OF THE INVENTION

The mobile device may have a problem that according to a change in the design of the mobile device, a circuit board pattern thereof needs to be newly designed and evaluated based on the position of switch or high-frequency characteristics such as wiring, whereby the manufacturing cost increases.

It is an object of the invention to provide a circuit board that is flexibly adaptable to any change in the design of the mobile device, as well as an electronic key using the circuit board.

According to an embodiment of the invention, a circuit board comprises a circuit board pattern forming a part of an electronic circuit and comprising a mounting pattern group on which a receiving means for receiving an operation can be mounted,

wherein the electronic circuit is established even when the receiving means is mounted on any mounting pattern of the mounting pattern group.

### Effects of the Invention

According to an embodiment of the invention, a circuit board can be provided that is flexibly adaptable to any change in the design of the mobile device, as well as an electronic key using the circuit board.

### BRIEF DESCRIPTION OF THE DRAWINGS

Next, the present invention will be explained in more detail in conjunction with appended drawings, wherein:

FIG. 1 is an exploded perspective view showing an electronic key which uses a circuit board in an embodiment;

FIG. 2A is a top view showing the circuit board in the embodiment;

FIG. 2B is a bottom view showing the circuit board;

FIG. 2C is an illustration diagram showing connection between a switch SW and a control circuit;

FIG. 2D is an illustration diagram showing connection between a switch SW1 and a switch SW2 in a module;

FIG. 3A is a top view showing a housing of the electronic key in the embodiment;

FIG. 3B is a cross sectional view taken along a line III(b)-III(b) in FIG. 3A and viewed in an arrow direction;

FIG. 3C is a bottom view showing the housing;

FIG. 3D is a side view taken from a left side through which a battery is inserted;

FIG. 3E is a perspective view showing a control circuit unit and a battery terminal which are housed in a battery housing portion;

FIG. 3F is a cross sectional view taken along a line III(f)-III(f) in FIG. 3C and viewed in an arrow direction;

FIGS. 4A to 4H are illustration diagrams showing arrangement examples of switches; and

FIGS. 5A to 5E are illustration diagrams showing examples of electronic keys with different designs;

FIG. 5F is an illustration diagram showing a modification of a circuit board pattern on the circuit board;

FIG. 5G is a top view showing another modification of the circuit board pattern; and

FIG. 5H is a cross sectional view showing the main portion of a dome-shaped cover arranged on the circuit board.

### DETAILED DESCRIPTION OF THE PREFERRED EMBODIMENTS

### Summary of Embodiments

A circuit board of the embodiment has a circuit board pattern constituting part of an electronic circuit and having mounting pattern groups on which a receiving means for receiving an operation can be mounted, and the circuit board is configured so that the electronic circuit is established whichever mounting pattern of the mounting pattern group mounts the receiving means.

This circuit board has the mounting pattern groups on which a receiving means can be mounted, in a such a way that a mounting pattern corresponding to a desired design can be selected from the mounting pattern groups and the receiving means can be mounted on the selected mounting pattern. Therefore, the circuit board is flexibly adaptable to any change in the design, unlike the case of changing the mounting position of the receiving means and the position of wiring according to the change in the design.

### EMBODIMENTS

### General Configuration of Electronic Key 1

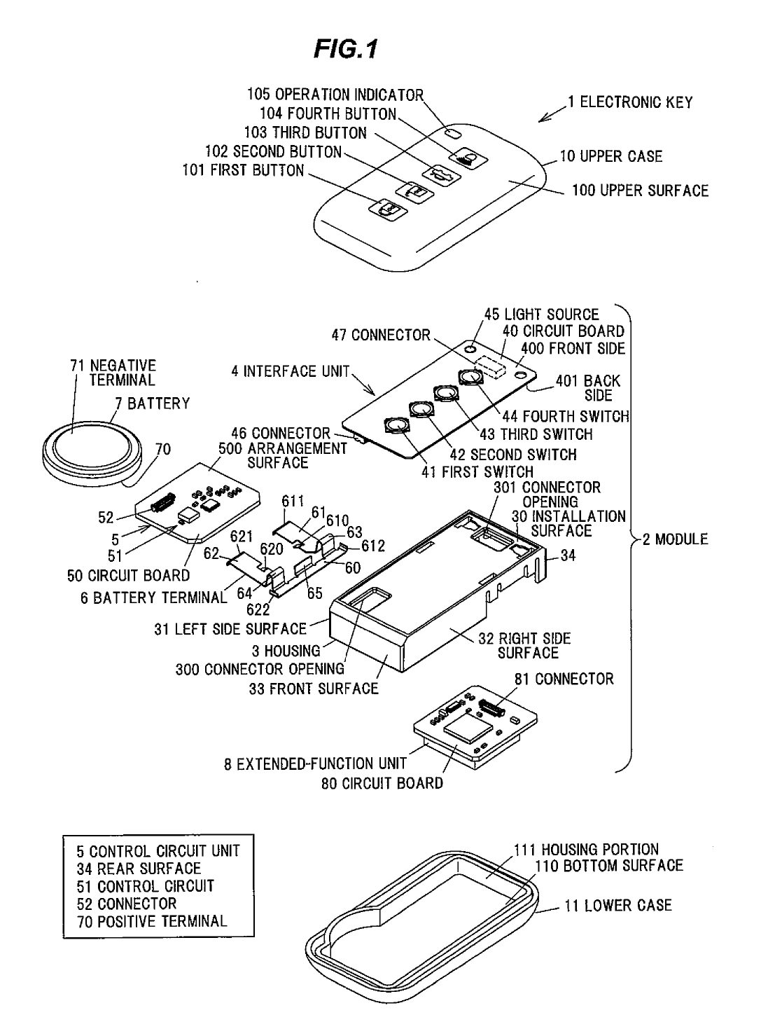

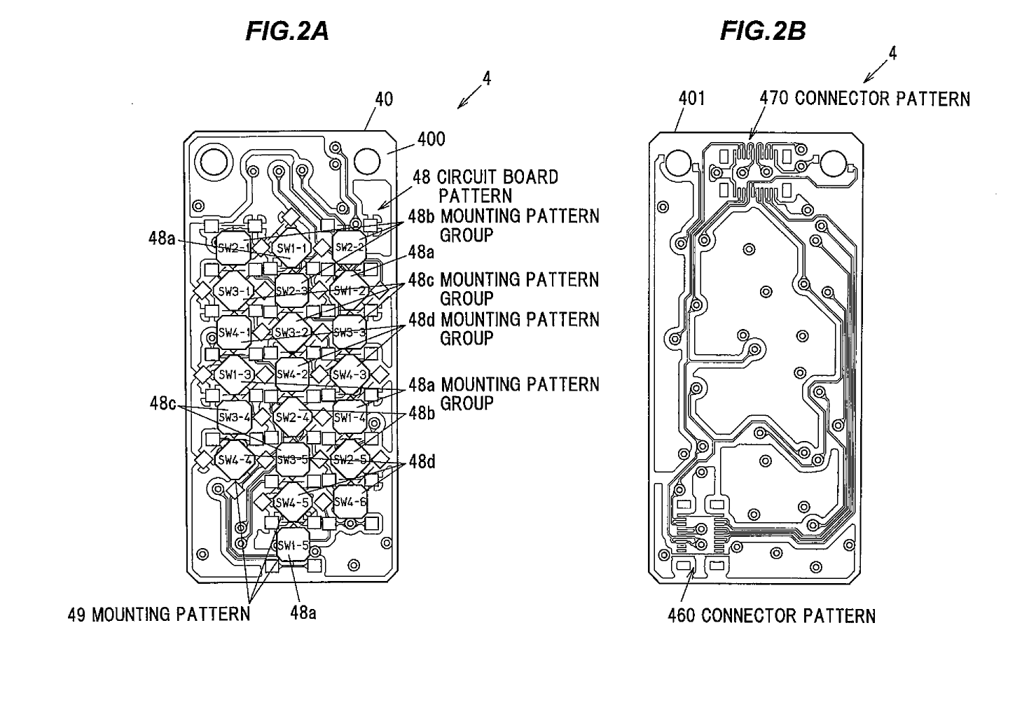

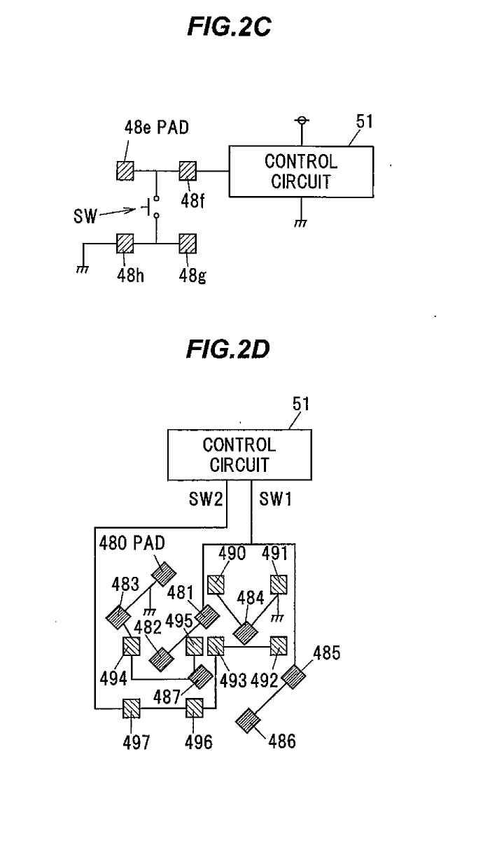

FIG. 1 is an exploded perspective view showing an electronic key which uses a circuit board in the embodiment. FIG. 2A is a top view showing the circuit board in the embodiment, FIG. 2B is a bottom view showing the circuit board, FIG. 2C is an explanatory schematic diagram illustrating connection between a switch SW and a control circuit and FIG. 2D is an explanatory schematic diagram illustrating connection between a switch SW1 and a switch SW2 in a module. A scale ratio in each drawing of the embodiment may be different from the actual scale ratio.

An electronic key 1 is a mobile device capable of wirelessly instructing, e.g., locking/unlocking of vehicle doors and engine starting, etc. The electronic key 1 in the present embodiment bi-directionally communicates with a vehicle for ID authentication, and a person bringing the electronic key 1 can, e.g., lock/unlock vehicle doors when authenticated.

The electronic key 1 has first to fourth buttons 101 to 104 arranged on an upper surface 100 of an upper case 10, as shown in FIG. 1. The first to fourth buttons 101 to 104 are configured to be push-operable.

The upper case 10 is formed to be integrated with a lower case 11. The electronic key 1 is configured so that the upper case 10 and the lower case 11 house a module 2, as shown in FIG. 1.

The module 2 is provided with a housing 3, an interface unit 4, a control circuit unit 5, a battery terminal 6 and a battery 7. Then, the interface unit 4 is provided with a circuit board 40.

The circuit board 40 has a circuit board pattern 48 constituting part of an electronic circuit and having mounting pattern groups on which a receiving means for receiving an operation can be mounted, and the circuit board 40 is configured so that the electronic circuit is established whichever mounting pattern 49 of the mounting pattern group mounts the receiving means.

The mounting pattern groups are, e.g., a mounting pattern group 48a having SW1-1 to SW1-5 as the mounting patterns 49, a mounting pattern group 48b having SW2-1 to SW2-5 as the mounting patterns 49, a mounting pattern group 48c having SW3-1 to SW3-5 as the mounting patterns 49, and a mounting pattern group 48d having SW4-1 to SW4-6 as the mounting patterns 49, as shown in FIG. 2A.

A device using the module 2 is not limited to the electronic key 1 and the module 2 may be used in a mobile device which is capable of locking/unlocking a front door of a house or remotely operating an electronic device.

Configuration of Upper Case 10 and Lower Case 11

The upper case 10 and the lower case 11 are formed of, e.g., a synthetic resin such as ABS (acrylonitrile butadiene styrene copolymer) resin or PC (polycarbonate) resin.

In addition to the first to fourth buttons 101 to 104, for example, an operation indicator 105 is arranged on the upper case 10. The first to fourth buttons 101 to 104 are configured to turn on first to fourth switches 41 to 44 of the module 2 based on the performed push-operation. Meanwhile, the operation indicator 105 emits light from a light source 45 of the module 2 (described later) when receiving the push-operation. An operator can know the reception of the operation by checking the light emitted from the operation indicator 105.

As shown in FIG. 1, a housing portion 111 having a shape corresponding to the shape of the module 2 is provided on a bottom surface 110 inside the lower case 11. The housing portion 111, together with the upper case 10, houses and holds the module 2. A recess which fits the shape of the battery 7 incorporated in the module 2 is formed on the housing portion 111. The battery 7 is a button cell and has a disc shape. The battery 7 has a positive terminal 70 at the upper portion and a negative terminal 71 at the lower portion having a smaller radius than the positive terminal 70.

The battery 7 is not limited to a button cell and may be a rechargeable battery as a modification. In case of using a rechargeable battery, the electronic key 1 is additionally provided with, e.g., an extended-function unit 8 (described later) allowing wireless charging of the rechargeable battery or an extended-function unit 8 allowing charging of the rechargeable battery through a cable.

The electronic key 1 may have a structure to incorporate a physical key as a backup in case that the module 2 cannot communicate with a vehicle. The physical key is arranged, e.g., between the housing portion 111 and the upper and lower cases 10, 11.

Configuration of Module 2

The module 2 is provided with the extended-function unit 8, in addition to the components mentioned above. The interface unit 4, the control circuit unit 5, the battery terminal 6, the battery 7 and the extended-function unit 8 of the module 2 are integrally housed in the housing 3.

The electronic key 1 can, e.g., lock/unlock doors based on the operation of a button when the extended-function unit 8 is not incorporated in the module 2. When the extended-function unit 8 is incorporated in the module 2, a function of the electronic key 1 is extended to allow an operator to, e.g., lock/unlock doors only by coming close to a vehicle or by touching the door.

Configuration of Housing 3

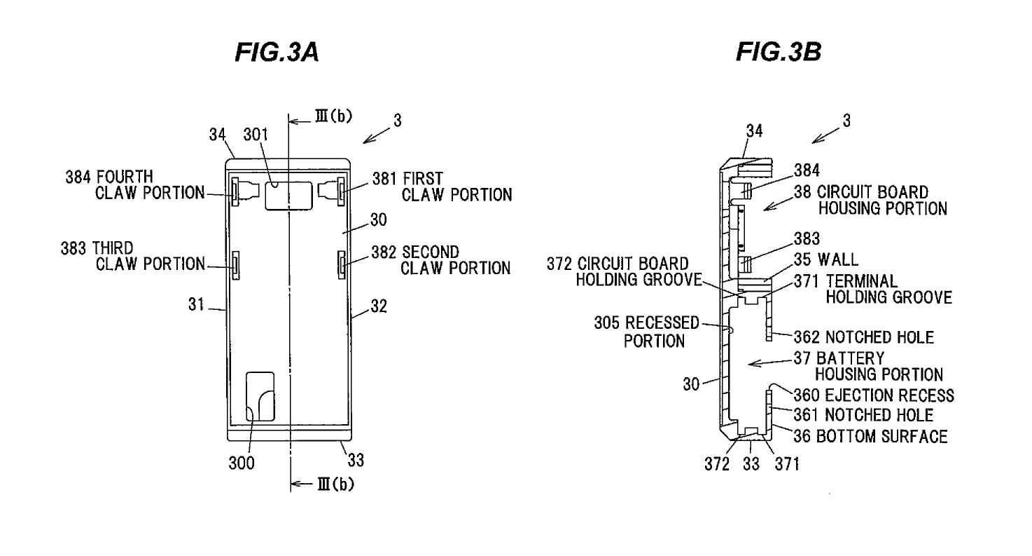

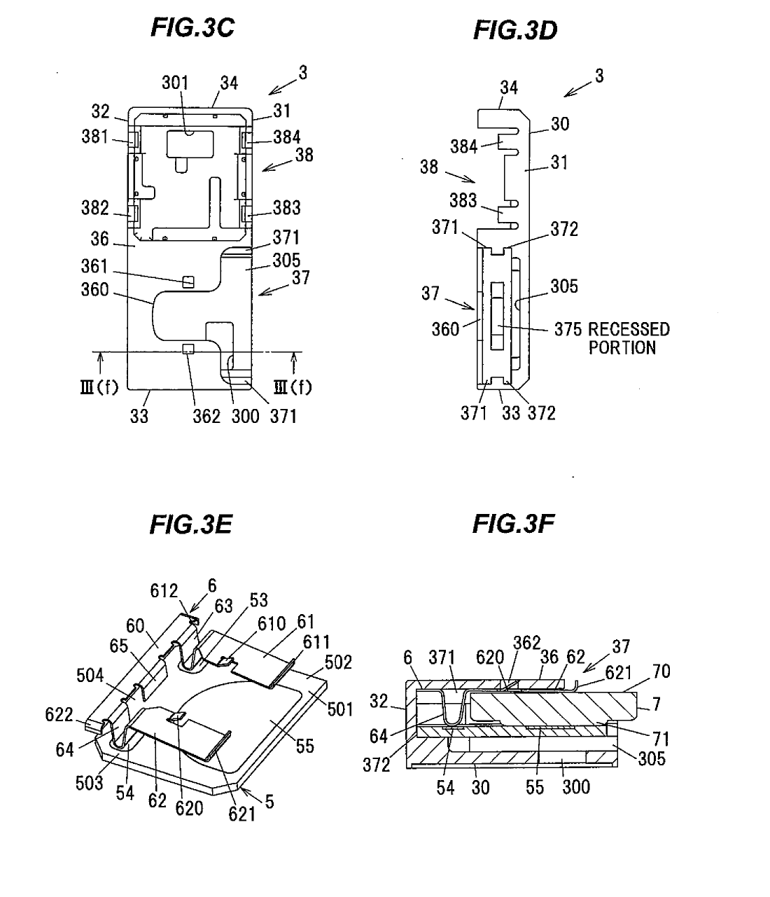

FIG. 3A is a top view showing a housing of the electronic key in the embodiment, FIG. 3B is a cross sectional view taken on line III(b)-III(b) of FIG. 3A when viewed in an arrow direction, FIG. 3C is a bottom view showing the housing, FIG. 3D is a side view when viewed from the left side from which a battery is inserted, FIG. 3E is a perspective view showing a control circuit unit and a battery terminal which are housed in a battery housing portion and FIG. 3F is a cross sectional view taken on line III(f)-III(f) of FIG. 3C when viewed in an arrow direction.

The housing 3 is formed of, e.g., a synthetic resin such as ABS resin or PC resin. The housing 3 has an installation surface 30 as a rectangular indent on the upper surface as shown in FIGS. 1 and 3A, and the interface unit 4 is arranged on the installation surface 30.

The housing 3 has a circuit board housing portion 38 for housing the extended-function unit 8 which has a different function from that of the first to fourth switches 41 to 44.

In detail, as shown in FIG. 3B, the housing 3 is divided by a wall 35 in such a way that a battery housing portion 37 is provided on a front surface 33 side and the circuit board housing portion 38 on the rear surface 34 side.

The housing 3 also has a connector opening 300 open on the battery housing portion 37 and a connector opening 301 open on the circuit board housing portion 38.

The connector openings 300 and 301 have a rectangular shape and are provided on the installation surface 30. The connector openings 300 and 301 are arranged so that, e.g., an angle formed between each other's longitudinal directions is 90°.

As shown in FIGS. 3D and 3F, the battery housing portion 37 is open on a left side surface 31, and has terminal holding grooves 371 for guiding insertion of the battery terminal 6 and circuit board holding groove 372 for guiding insertion of a circuit board 50 which are provided on facing side surfaces. The facing side surfaces are a side surface on the wall 35 side and a side surface on the front surface 33 side inside the battery housing portion 37.

In addition, in the battery housing portion 37, a recessed portion 305 for housing a connector 52, etc., arranged on the circuit board 50 is provided on the installation surface 30 side and a recessed portion 375 corresponding to the outer shape of the battery 7 is provided on a right side surface 32 side.

An ejection recess 360 recessed along an ejection direction of the battery 7 is formed on a bottom surface 36 of the battery housing portion 37 to facilitate ejection of the battery 7 housed in the battery housing portion 37. As shown in FIG. 3C, rectangular notched holes 361 and 362 are formed on both sides of the ejection recess 360. The notched holes 361 and 362 are provided so that protruding portions 610 and 620 of the battery terminal 6 (described later) are fitted thereto when the battery 7 is housed in the battery housing portion 37. The battery terminal 6 is prevented from slipping out of the battery housing portion 37 by fitting the protruding portions 610 and 620 to the notched holes 361 and 362.

The connector opening 300 is provided on the battery housing portion 37, and the connector 52 of the circuit board 50 of the control circuit unit 5 (described later) is connected to a connector 46 of the interface unit 4 through the connector opening 300.

A circuit board 80 of the extended-function unit 8 is housed in the circuit board housing portion 38. On the circuit board housing portion 38, first to fourth claw portions 381 to 384 are provided in a clockwise direction in the plane of FIG. 3A. The first claw portion 381 and the second claw portion 382 are arranged side by side, and so are the third claw portion 383 and the fourth claw portion 384. The first claw portion 381 faces the fourth claw portion 384 and the second claw portion 382 faces the third claw portion 383. The side portion of the circuit board 80 is fitted to the first to fourth claw portions 381 to 384 which thereby hold the circuit board 80.

The connector opening 301 is provided on the circuit board housing portion 38, and a connector 81 of the circuit board 80 is connected to a connector 47 of the interface unit 4 through the connector opening 301.

Configuration of Interface Unit 4

The interface unit 4 is composed of e.g., receiving means for receiving an operation by an operator and an indicating means for indicating the reception of the operation. In detail, the interface unit 4 has, e.g., a light source, a switch, a touch sensor, a display, a microphone, a speaker, a camera and a solar cell panel, etc. The receiving means in the present embodiment is the first to fourth switches 41 to 44, as an example.

The interface unit 4 is further provided with, e.g., the light source 45 on a front side 400 of the circuit board 40. In addition, the interface unit 4 is provided with the connectors 46 and 47 on a back side 401 of the circuit board 40.

The circuit board 40 of the interface unit 4 is, e.g., a long, rectangular printed circuit board, as shown in FIGS. 2A and 2B. The circuit board 40 has a shape corresponding to the shape of the installation surface 30 of the housing 3.

The first to fourth switches 41 to 44 are, e.g., surface-mounted microswitches. The first to fourth switches 41 to 44 are arranged in line so as to correspond to the arrangement of the first to fourth buttons 101 to 104 on the upper case 10.

The first switch 41 is turned on by push-operation on the first button 101 and, as an example, doors of a vehicle are locked. The second switch 42 is turned on by push-operation on the second button 102 and, as an example, the doors of the vehicle are unlocked. The third switch 43 is turned on by push-operation on the third button 103 and, as an example, the trunk of the vehicle opens. The fourth switch 44 is turned on by push-operation on the fourth button 104 and, as an example, the alarm of the vehicle is armed.

Switch signals output from the first to fourth switches 41 to 44 are sent to, e.g., the control circuit unit 5 via the connector 46. According to the input switch signal, the control circuit unit 5 generates a transmission signal to be sent to the vehicle and wirelessly outputs the generated transmission signal to the vehicle.

The light source 45 is constructed from, e.g., a light-emitting element. When the first to fourth switches 41 to 44 are turned on, the light source 45 receives power from the battery 7 via the connectors 52 and 46 and emits light.

Next, the circuit board pattern 48 formed on the circuit board 40 of the interface unit 4 will be described below.

As shown in FIG. 2A, the circuit board 40 has the circuit board pattern 48 on which plural switches SW can be arranged. The circuit board pattern 48 is configured that, e.g., four switches SW can be mounted.

As shown in FIG. 2C, the switch SW is electrically connected to, e.g., pads 48e to 48h. The pads 48e and 48f, which are electrically connected to one terminal of the switch SW, are electrically connected to each other and are also electrically connected to a control circuit 51. Meanwhile, the pads 48g and 48h, which are electrically connected to the other terminal of the switch SW, are electrically connected to each other and are also grounded. Depression of a button corresponding to the switch SW electrically connects the pads 48e, 48f to the pads 48g, 48h.

As shown in FIG. 2A, the circuit board pattern 48 not only simply allows four switches SW1 to SW4 to be arranged thereon, but also allows the switch SW1 to be arranged on any one of the mounting patterns 49 indicated as SW1-1 to SW1-5 of the mounting pattern group 48a, the switch SW2 to be arranged on any one of the mounting patterns 49 indicated as SW2-1 to SW2-5 of the mounting pattern group 48b, the switch SW3 to be arranged on any one of the mounting patterns 49 indicated as SW3-1 to SW3-5 of the mounting pattern group 48c, and the switch SW4 to be arranged on any one of the mounting patterns 49 indicated as SW4-1 to SW4-6 of the mounting pattern group 48d.

In detail, the circuit board pattern 48 allows each switch to be arranged on any mounting pattern 49 without changing the wiring or the positions of the pads to be connected to the switch. In other words, the switch SW1 is arranged on any one of the mounting patterns 49 (SW1-1 to SW1-5) shown in FIG. 2A. The switch SW2 is arranged on any one of the mounting patterns 49 (SW2-1 to SW2-5) shown in FIG. 2A. The switch SW3 is arranged on any one of the mounting patterns 49 (SW3-1 to SW3-5) shown in FIG. 2A. The switch SW4 is arranged on any one of the mounting patterns 49 (SW4-1 to SW4-6) shown in FIG. 2A.

Next, an example of electrical connection between the mounting patterns 49 (SW1-1, SW1-2, SW2-2 and SW2-3) shown in FIG. 2D will be described.

The circuit board pattern 48 is configured such that that one pad (or terminal, e.g., pads 481, 482, 485 and 486 in FIG. 2D connected to the control circuit 51) of the mounting pattern 49 belonging to a mounting pattern group may be shared (or commonly used) and another pad (or terminal, e.g., pads 490, 491, 484, 487, 494 and 495 in FIG. 2D grounded) of the mounting pattern 49 belonging to a different mounting pattern group may be shared (or commonly used).

In detail, SW1-1 has pads 480 to 483. SW1-2 has pads 484 to 487. SW2-2 has pads 490 to 493. SW2-3 has pads 494 to 497.

The pads 480, 483, 487, 494 and 495 are electrically connected to each other and are also grounded. The pads 481 and 482 are electrically connected to each other and are also electrically connected to the control circuit 51. The pads 485 and 486 are electrically connected to each other and are also electrically connected to the control circuit 51.

The pads 484, 490 and 491 are electrically connected to each other and are also grounded. The pads 492, 493, 496 and 497 are electrically connected to each other and are also electrically connected to the control circuit 51.

Since the pads of SW1-1, SW1-2, SW2-2 and SW2-3 are connected as described above, for example, the switch SW1 can be arranged on SW1-1 or SW1-2 and the switch SW2 on SW2-2 or SW2-3.

Here, the switches arranged on the circuit board pattern 48 may be at least one of the four switches. In addition, since the control circuit 51 determines SW1 to SW 4, the switch can be arranged on the mounting pattern 49 for any of SW1 to SW 4 regardless of the sequence of the buttons arranged on the upper case 10.

As shown in FIG. 2B, connector patterns 460 and 470 are formed on the back side 401 of the circuit board 40. The connector 46 is connected to the connector pattern 460 and the connector 47 is connected to the connector pattern 470. The connector patterns 460 and 470 are electrically connected to the circuit board pattern 48 on the front side 400. Thus, the extended-function unit 8 is electrically connected to the control circuit 51 of the control circuit unit 5 via the circuit board pattern 48 of the circuit board 40.

Next, an example arrangement of switches will be described below.

Arrangement of Switches

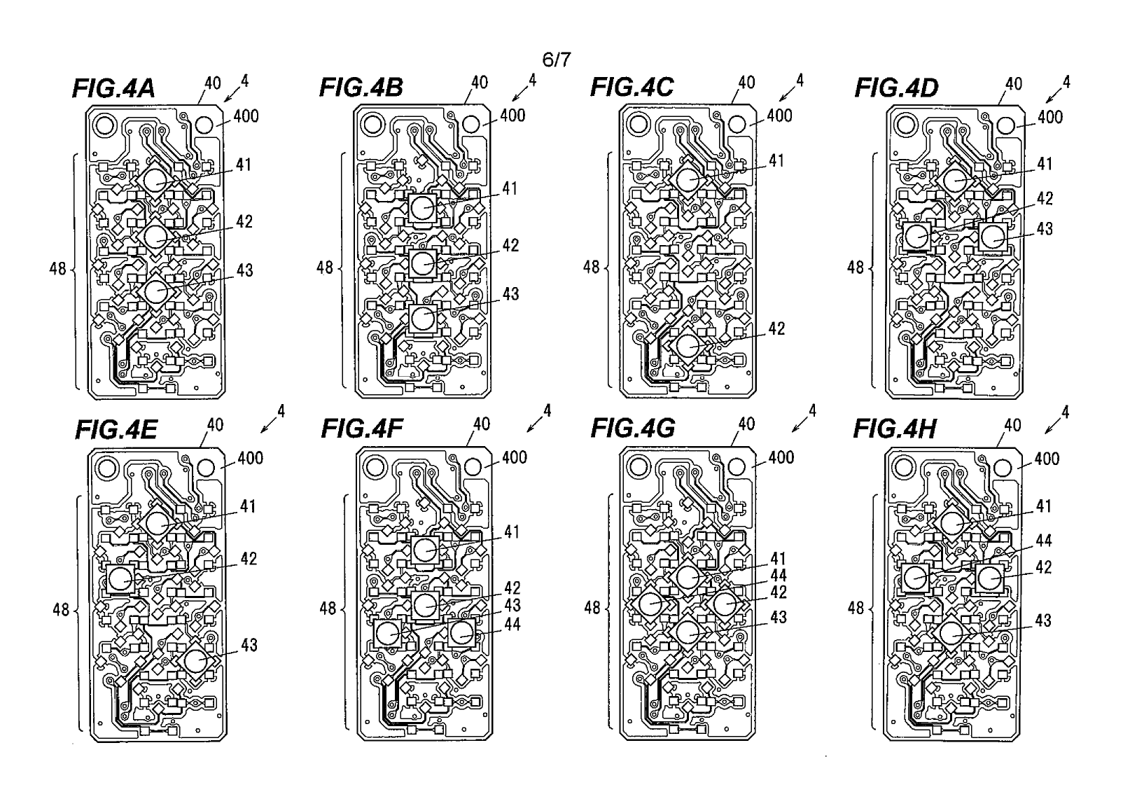

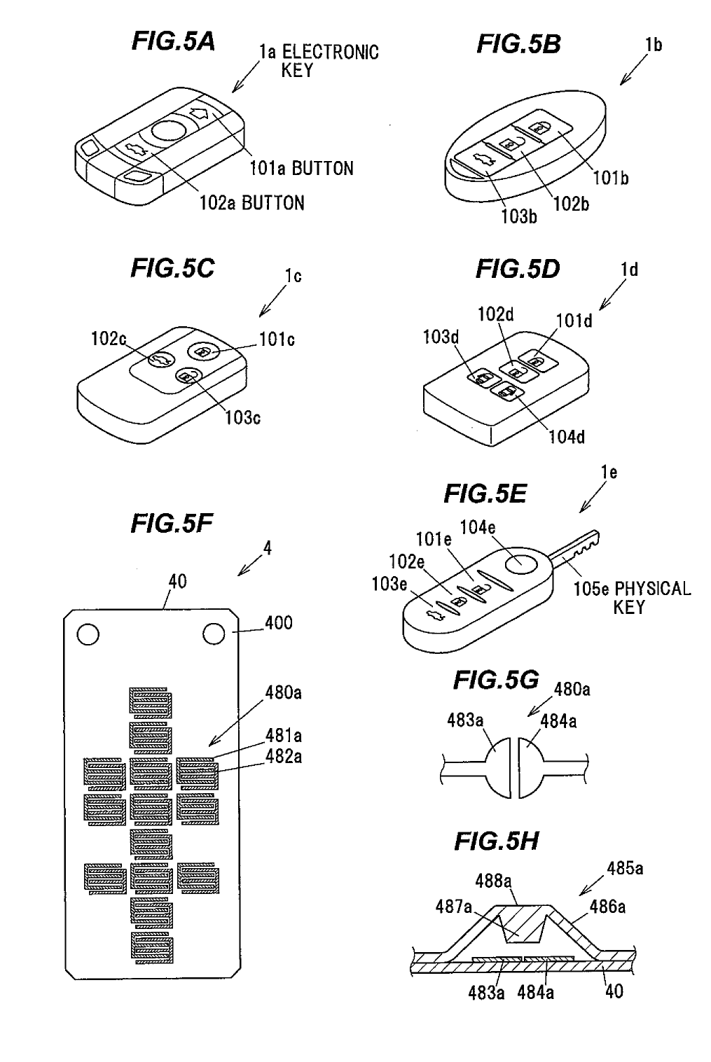

FIGS. 4A to 4H are schematic diagrams illustrating examples of arrangement of switches. FIGS. 5A to 5E are schematic diagrams illustrating examples of electronic keys with different designs, FIG. 5F is a schematic diagram illustrating a modification of a circuit board pattern on the circuit board, FIG. 5G is a top view showing another modification of the circuit board pattern and FIG. 5H is a cross sectional view showing the main portion of a dome-shaped cover arranged on the circuit board.

On the circuit board 40 shown in FIG. 4A, three switches are arranged in line. In detail, the first switch 41 is mounted on the SW1-1 mounting pattern 49 of the mounting pattern group 48a, the second switch 42 is mounted on the SW2-3 mounting pattern 49 of the mounting pattern group 48b, and the third switch 43 is mounted on the SW3-2 mounting pattern 49 of the mounting pattern group 48c.

On the circuit board 40 shown in FIG. 4B, three switches are arranged in line in the similar manner. However, the arrangement thereof is different from that shown in FIG. 4A. In detail, the first switch 41 is mounted on the SW2-3 mounting pattern 49 of the mounting pattern group 48b, the second switch 42 is mounted on the SW3-2 mounting pattern 49 of the mounting pattern group 48c, and the third switch 43 is mounted on the SW4-2 mounting pattern 49 of the mounting pattern group 48d.

In FIGS. 5B and 5E, electronic keys 1b and 1e designed to have three switches arranged as described above are shown as an example. However, the switches of the electronic keys 1b and 1e are mounted on the different mounting patterns 49 from those in FIGS. 4A and 4B.

On the electronic key 1b shown in FIG. 5B, buttons 101b to 103b are arranged, e.g., in line in a longitudinal direction. As an example, the electronic key 1b is configured that the first switch 41 corresponding to the button 101b is arranged on SW1-1 of the circuit board pattern 48, the second switch 42 corresponding to the button 102b is arranged on SW3-2 and the third switch 43 corresponding to the button 103b is arranged on SW2-4.

The electronic key 1e shown in FIG. 5E has buttons 101e to 103e arranged in line, a push-button 104e and a physical key 105e. As an example, the switches corresponding to the buttons 101e to 103e are arrange on the same mounting patterns 49 as those in the electronic key 1b. As an example, the physical key 105e is pivotally ejected from the side of the case by depressing the push-button 104e and is arranged between the module 2 and the case of the electronic key 1e.

On the circuit board 40 shown in FIG. 4C, two switches are arranged in the longitudinal direction. In detail, the first switch 41 is mounted on the SW1-1 mounting pattern 49 of the mounting pattern group 48a and the second switch 42 is mounted on the SW4-5 mounting pattern 49 of the mounting pattern group 48d.

An electronic key 1a shown in FIG. 5A is an example of such an electronic key designed to have two switches arranged as described above.

On the electronic key 1a shown in FIG. 5B, buttons 101a and 102a are, e.g., arranged apart in the longitudinal direction. As an example, the electronic key 1a is configured that the first switch 41 corresponding to the button 101a is arranged on SW1-1 of the circuit board pattern 48, and the second switch 42 corresponding to the button 102a is arranged on SW4-5.

On the circuit board 40 shown in FIG. 4D, three switches are respectively arranged at the vertices of a triangle. In detail, the first switch 41 is mounted on the SW1-1 mounting pattern 49 of the mounting pattern group 48a, the second switch 42 is mounted on the SW4-1 mounting pattern 49 of the mounting pattern group 48d, and the third switch 43 is mounted on the SW3-3 mounting pattern 49 of the mounting pattern group 48c.

In FIG. 5C, an electronic key 1c designed to have three switches arranged at the vertices of a triangle as described above is shown as an example.

On the electronic key 1c shown in FIQSC, buttons 101c to 103c are arranged, e.g., at the vertices of a triangle. As an example, the electronic key 1c is configured that the first switch 41 corresponding to the button 101c is arranged on SW1-1 of the circuit board pattern 48, the second switch 42 corresponding to the button 102c is arranged on SW4-1 and the third switch 43 corresponding to the button 103c is arranged on SW3-3.

On the circuit board 40 shown in FIG. 4E, the third switch 43 is arranged apart from the first switch 41 and the second switch 42, as an example. In detail, the first switch 41 and the second switch 42 are mounted in the same arrangement as that shown in

FIG. 4D and the third switch 43 is mounted on the SW2-5 mounting pattern 49 of the mounting pattern group 48b.

On the circuit board 40 shown in FIG. 4F, four switches are arranged. In detail, the first switch 41 is mounted on the SW2-3 mounting pattern 49 of the mounting pattern group 48b, the second switch 42 is mounted on the SW4-2 mounting pattern 49 of the mounting pattern group 48d, the third switch 43 is mounted on the SW3-4 mounting pattern 49 of the mounting pattern group 48c, and the fourth switch 44 is mounted on the SW1-4 mounting pattern 49 of the mounting pattern group 48a.

In FIG. 5D, an electronic key 1d designed to have four switches arranged as described above is shown as an example.

On the electronic key 1d shown in FIG. 5D, for example, buttons 101d and 102d are arranged side by side in the longitudinal direction and buttons 103d and 104d are arranged side by side in the lateral direction. The buttons 103d and 104d are buttons to, e.g., open/close sliding doors on both sides of a vehicle and are arranged next to one another so as to correspond to the right and left sides of the vehicle.

As an example, the electronic key 1d is configured that the first switch 41 corresponding to the button 101d is arranged on SW2-3 of the circuit board pattern 48, the second switch 42 corresponding to the button 102d is arranged on SW4-2, the third switch 43 corresponding to the button 103d is arranged on SW3-4, and the fourth switch 44 corresponding to the button 104d is arranged on SW1-4.

On the circuit board 40 shown in. FIG. 4G, the four switches are respectively arranged at the ends of the arms of a cross. In detail, the first switch 41 is mounted on the SW3-2 mounting pattern 49 of the mounting pattern group 48c, the second switch 42 is mounted on the SW4-3 mounting pattern 49 of the mounting pattern group 48d, the third switch 43 is mounted on the SW2-4 mounting pattern 49 of the mounting pattern group 48b, and the fourth switch 44 is mounted on the SW1-3 mounting pattern 49 of the mounting pattern group 48a.

On the circuit board 40 shown in FIG. 4H, the four switches are respectively arranged at the ends of the arms of a different cross. In detail, the first switch 41 is mounted on the SW1-1 mounting pattern 49 of the mounting pattern group 48a, the second switch 42 is mounted on the SW3-3 mounting pattern 49 of the mounting pattern group 48c, the third switch 43 is mounted on the SW2-4 mounting pattern 49 of the mounting pattern group 48b, and the fourth switch 44 is mounted on the SW4-1 mounting pattern 49 of the mounting pattern group 48d.

As such, the circuit board 40 having plural mounting pattern groups as described above is widely adaptable to various switch arrangements.

Although the circuit board pattern 48 is configured so that switches are arranged thereon, it is not limited thereto. As a modification, the circuit board pattern 48 may be configured such that, e.g., a conductive member comes into contact with two terminals arranged on the circuit board 40 when a button is push-operated and the two terminals are electrically conducted through the member.

A circuit board pattern 480a shown in FIQ. 5F is formed by arranging first and second terminals 481a and 482a having a comb shape to mesh with each other. In FIG. 5F, illustration of wiring, etc., electrically connected to the first and second terminals 481a and 482a is omitted.

As an another modification, the circuit board pattern 480a shown in FIG. 5G is provided with first and second terminals 483a and 484a having a semicircular shape which are arranged to face each other.

The circuit board pattern 480a in the modifications functions as, e.g., a switch in combination with a dome-shaped cover 485a, as shown in FIG. 5H. The dome-shaped cover 485a has a hemispherical dome 486a provided so as to correspond to the arrangement of the circuit board pattern 480a. The dome-shaped cover 485a is formed of, e.g., a resin such as silicone.

An upper surface 488a of the dome 486a comes into contact with a back side of a button of an electronic key. The dome 486a also has a contact 487a which is provided to face the first and second terminals 483a and 484a.

The contact 487a has a conductivity. Thus, when the dome 486a is deformed by depressing the button, the contact 487a comes into contact with the first and second terminals 483a and 484a, and the first terminal 483a and the second terminal 484a are thereby electrically conducted. After finishing the operation, the dome 486a is restored to the original shape by a restoring force and electrical conduction between first and second terminals 483a and 484a is interrupted.

Also, when the dome-shaped cover 485a is combined with the circuit board pattern 480a shown in FIG. 5F, the contact 487a comes into contact with the first and second terminals 481a and 482a by depression of the button, and the first terminal 481a and the second terminal 482a are electrically conducted through the contact 487a.

Configuration of Control Circuit Unit 5

As shown in FIG. 1, the control circuit unit 5 is provided with the circuit board 50, the control circuit 51, the connector 52, a first positive terminal 53, a second positive terminal 54 and a negative terminal 55.

The circuit board 50 is, e.g., a rectangular printed circuit board. The control circuit 51 and the connector 52 are arranged on an arrangement surface 500 of the circuit board 50. Meanwhile, the first positive terminal 53, the second positive terminal 54 and the negative terminal 55 are arranged on a terminal surface 501 which is a back side of the arrangement surface 500 of the circuit board 50.

The control circuit 51 is composed of, e.g., a control unit including CPU (Central Processing Unit), etc., and a communication unit for wirelessly communicating with a vehicle, etc. The control circuit 51 is electrically connected to the first positive terminal 53, the second positive terminal 54 and the negative terminal 55. The control circuit 51 is also electrically connected to the connector 52. In addition, the control circuit 51, together with the receiving means mounted on the circuit board pattern 48, forms an electronic circuit.

The first positive terminal 53, the second positive terminal 54 and the negative terminal 55 are formed of, e.g., a conductive metal material such as copper, or an alloy material containing thereof, and is formed into a plate shape. Alternatively, the control circuit unit 5 may be provided with only one of the first positive terminal 53 and the second positive terminal 54, or may be provided with a terminal having a shape formed by connecting the first positive terminal 53 to the second positive terminal 54.

Configuration of Battery Terminal 6

The battery terminal 6 is formed of, e.g., a conductive metal material such as copper, or an alloy material containing thereof.

As shown in FIG. 3E, the battery terminal 6 has a base portion 60 elongated in a direction intersecting with an insertion direction of the battery 7, first and second terminals 61 and 62 extending from both ends of the base portion 60 in a direction opposite to the insertion direction and coming into contact with one of the terminals of the inserted battery 7, and curved portions 63 and 64 respectively provided on the first and second terminals 61 and 62 so as to curve toward the circuit board 50 and respectively coming into contact with the first positive terminal 53 to the second positive terminal 54 of the circuit board 50.

The base portion 60 has a supporting portion 65 and guide portions 612 and 622. The supporting portion 65 is provided at the center of the base portion 60 on a side surface on the first and second terminals 61 and 62 side. A portion protruding from the side surface of the base portion 60 is bend in the same direction as the curved portions 63 and 64 and the supporting portion 65 is thereby formed. The supporting portion 65 serves to, e.g., prevent deformation of the base portion 60 due to insertion of the battery 7, etc.

As shown in FIG. 3E, an end portion of the base portion 60 on the first terminal 61 side is bent in the same direction as the curved portion 63 and the guide portion 612 is thereby formed. The guide portion 612 is inserted into the terminal holding groove 371 of the battery housing portion 37 on the wall 35 side.

As shown in FIG. 3E, an end portion of the base portion 60 on the second terminal 62 side is bent in the same direction as the curved portion 64 and the guide portion 622 is thereby formed. The guide portion 622 is inserted into the terminal holding groove 371 of the battery housing portion 37 on the front surface 33 side.

The first terminal 61 has the curved portion 63 on the base portion 60 side and a front end portion 611 on the opposite side. The first terminal 61 is also provided with the protruding portion 610 which protrudes in a direction opposite to the side to be in contact with the battery 7.

The curved portion 63 is formed by bending a portion of the first terminal 61 on the base portion 60 side into a substantially oval shape. As shown in FIG. 3F, when the control circuit unit 5, the battery terminal 6 and the battery 7 are housed in the battery housing portion 37, the curved portion 63 generates an elastic force due to deformation and comes into contact with the first positive terminal 53 of the circuit board 50. Contact pressure between the curved portion 63 and the first positive terminal 53 is ensured by the elastic force.

Since the first terminal 61 is in contact with the positive terminal 70 of the inserted battery 7, the first positive terminal 53 is electrically connected to the positive terminal 70 via the battery terminal 6.

A lateral portion of the first terminal 61 on the inner side is bent at a position on the curved portion 63 side, and the protruding portion 610 is thereby formed. In more detail, the protruding portion 610 is formed by bending and lifting up a portion on the opposite side to the curved portion 63, i.e., on the front end portion 611 side, toward the bottom surface 36 of the housing 3.

The front end portion 611 is formed by bending an front end of the first terminal 61 in the same direction as the protruding portion 610. The front end portion 611 is provided to facilitate insertion of the battery 7.

The second terminal 62 has the curved portion 64 on the base portion 60 side and a front end portion 621 on the opposite side. The second terminal 62 is also provided with the protruding portion 620 which protrudes in a direction opposite to the side to be in contact with the battery 7.

The curved portion 64 is formed by bending a portion of the second terminal 62 on the base portion 60 side into a substantially oval shape. As shown in FIG. 3F, when the control circuit unit 5, the battery terminal 6 and the battery 7 are housed in the battery housing portion 37, the curved portion 64 generates an elastic force due to deformation and comes into contact with the second positive terminal 54 of the circuit board 50. Contact pressure between the curved portion 64 and the second positive terminal 54 is ensured by the elastic force.

Since the second terminal 62 is in contact with the positive terminal 70 of the inserted battery 7, the second positive terminal 54 is electrically connected to the positive terminal 70 via the battery terminal 6.

A lateral portion of the second terminal 62 on the inner side is bent at a position on the curved portion 64 side, and the protruding portion 620 is thereby formed. In more detail, the protruding portion 620 is formed by bending and lifting up a portion on the opposite side to the curved portion 64, i.e., on the front end portion 621 side, toward the bottom surface 36 of the housing 3.

The front end portion 621 is formed by bending an front end of the second terminal 62 in the same direction as the protruding portion 620. The front end portion 621 is provided to facilitate insertion of the battery 7 in the same manner as the front end portion 611.

Next, how to assemble the control circuit unit 5, the battery terminal 6 and the battery 7 will be described below.

How to Assemble Battery Terminal 6 Etc.

Assembly of Battery Terminal 6

Firstly, the guide portions 612 and 622 of the battery terminal 6 are fitted to the terminal holding grooves 371 of the battery housing portion 37 of the housing 3 and the battery terminal 6 is then inserted into the battery housing portion 37, thereby assembling the battery terminal 6 to the battery housing portion 37.

In detail, when the guide portions 612 and 622 are inserted into the terminal holding grooves 371, the guide portions 612 and 622 deform inward since a distance between the grooves is smaller than a distance between the guide portions 612 and 622. Contact between the guide portions 612, 622 and the terminal holding grooves 371 is maintained by the deformation.

Assembling of Control Circuit Unit 5

Next, edges 502 and 503 of the circuit board 50 of the control circuit unit 5 are fitted into the circuit board holding grooves 372 of the battery housing portion 37, thereby assembling the control circuit unit 5 to the battery housing portion 37.

Assembling of Battery 7

Next, the battery 7 is inserted between the first and second terminals 61, 62 and the circuit board 50, thereby assembling the battery 7 to the battery housing portion 37.

In detail, when the battery 7 is inserted into the battery housing portion 37, the perimeter portion of the battery 7 firstly comes into contact with the front end portion 611 of the first terminal 61 and the front end portion 621 of the second terminal 62, and the battery 7 then pushes the first and second terminals 61 and 62 upward through the front end portions 611 and 621. When the battery 7 is further inserted into the battery housing portion 37 and is then housed in the battery housing portion 37, the first and second terminals 61 and 62 are further pushed up and the protruding portion 610 is fitted into the notched hole 361 and the protruding portion 620 into the notched hole 362, as shown in FIG. 3F.

Also, when the battery 7 is housed in the battery housing portion 37, the positive terminal 70 of the battery 7 comes into contact with the first terminal 61 as well as the second terminal 62 and the negative terminal 71 of the battery 7 comes into contact with the negative terminal 55 of the circuit board 50, as shown in FIG. 3F. The battery 7 is sandwiched between the first and second terminals 61, 62 and the circuit board 50, and an elastic force of the first and second terminals 61 and 62 maintains contact of the first and second terminals 61 and 62 with the positive terminal 70 and contact of the negative terminal 71 with the negative terminal 55.

Once assembled, the positive terminal 70 of the battery 7 is electrically connected to the first positive terminal 53 and the second positive terminal 54 of the circuit board 50 via the battery terminal 6, the negative terminal 71 of the battery 7 is electrically connected to the negative terminal 55 of the circuit board 50, and the battery 7 is thus electrically connected to the control circuit 51.

### Effects of the Embodiment

The electronic key 1 in the present embodiment is flexibly adaptable to a change in the design. In detail, since the interface unit 4 provided with the first to fourth switches 41 to 44 and the control circuit unit 5 provided with the control circuit 51 are formed on the separate circuit boards in the electronic key 1, the electronic key 1 can be adapted to a different electronic key design by changing, e.g., the positions of the switches of the interface unit 4. Since the circuit board 40 of the interface unit 4 allows a switch to be arranged on any mounting pattern 49 of a mounting pattern group, it is possible to flexibly change the arrangement of switches by providing plural mounting pattern groups. Therefore, the electronic key 1 is more flexibly adaptable to a change in the design than an electronic key in which a receiving means for receiving an operation and a control unit are provided on the same circuit board.

Since, in the electronic key 1, the interface unit 4 is independent from the control circuit unit 5 and also the switches can be arranged flexibly, it is not necessary to change the pattern for every electronic key design. This means that the electronic key 1 can be manufactured at low cost since redesign and evaluation of the circuit board pattern 48 due to a change in a switch position or a change in a wiring position based on high-frequency characteristics are not required and it is adaptable to plural designs while using the same circuit board 40. In addition, it is easy to change the specification of the electronic key 1 since the circuit board 40 of the interface unit 4 can be exchanged with a circuit board having a different function without changing the circuit board 50 of the control circuit unit 5 having a control function.

Since each signal line is shared by multiple pads in the circuit board 40 of the interface unit 4, the arrangement of the receiving means, etc., can be varied by changing a program of the control circuit unit 5 associated with installation of the receiving means.

Since the extended-function unit 8 is exchangeable, the electronic key 1 can be flexibly used as an electronic key having a different specification.

In the electronic key 1, the extended-function unit 8 is electrically connected to the control circuit 51 of the control circuit unit 5 via the circuit board 40 of the interface unit 4. In other words, the circuit board 40 is electrically connected to the control circuit unit 5 via the connector 46 and is electrically connected to the extended-function unit 8 via the connector 47.

Although the embodiment and some modifications of the invention have been described, the embodiment and modifications are merely an example and the invention according to claims is not to be limited thereto. These new embodiment and modifications may be implemented in various other forms, and various omissions, substitutions and changes, etc., can be made without departing from the gist of the invention. In addition, all combinations of the features described in the embodiment and modifications are not necessary to solve the problem of the invention. Further, the embodiment and modifications thereof are included within the scope and gist of the invention and also within the invention described in the claims and the range of equivalency.

What is claimed is:

1. A circuit board, comprising a circuit board pattern forming a part of an electronic circuit and comprising a mounting pattern group on which a receiving means for receiving an operation can be mounted,
wherein the electronic circuit is established even when the receiving means is mounted on any mounting pattern of the mounting pattern group.

2. The circuit board according to claim 1, wherein the mounting pattern group comprises a plurality of mounting pattern groups.

3. The circuit board according to claim 2, wherein one terminal is commonly used between the mounting patterns belonging to same one of the mounting pattern group.

4. The circuit board according to claim 1, further comprising a connector electrically connected to a control circuit board comprising a control circuit of the electronic circuit.

5. An electronic key, comprising the circuit board according to claim 1.

6. The circuit board according to claim 2, wherein another terminal is commonly used between the mounting patterns belonging to different one of the mounting pattern groups.

7. The circuit board according to claim 2, wherein the mounting pattern groups are separately and electrically connected to a control circuit board comprising a control circuit of the electronic circuit.

8. The circuit board according to claim 2, wherein the mounting pattern groups are arranged in a pattern different from each other.
